(19) United States
(12) Patent Application Publication
(10) Pub. No.: US 2025/0254852 A1
(43) Pub. Date: Aug. 7, 2025

(54) SEMICONDUCTOR DEVICE, AND ELECTRONIC APPARATUS AND MEMORY DEVICE BOTH INCLUDING THE SEMICONDUCTOR DEVICE

(71) Applicant: Samsung Electronics Co., Ltd., Suwon-si (KR)

(72) Inventors: Moonil JUNG, Suwon-si (KR); Sangwook KIM, Suwon-si (KR); Younjin JANG, Suwon-si (KR); Kyooho JUNG, Suwon-si (KR)

(73) Assignee: Samsung Electronics Co., Ltd., Suwon-si (KR)

(21) Appl. No.: 19/018,747

(22) Filed: Jan. 13, 2025

(30) Foreign Application Priority Data
Feb. 1, 2024 (KR) 10-2024-0016217

(51) Int. Cl. H10B 10/00; H10D 30/67; H10D 64/68

(52) U.S. Cl. CPC H10B 10/125; H10D 30/6735; H10D 30/6756; H10D 30/6757; H10D 64/689

(57) ABSTRACT

Provided are a semiconductor device, and/or an electronic device and a memory device both including the semiconductor device. The semiconductor device includes a lower electrode, an upper electrode spaced apart from the lower electrode, a channel layer between the lower electrode and the upper electrode, a gate insulating layer in the channel layer, an insertion layer provided between the channel layer and the gate insulating layer, and a gate electrode on the gate insulating layer. The channel layer has a vertical channel structure extending in a vertical direction from the lower electrode toward the upper electrode. The insertion layer may include a nitride of a metal and/or an oxynitride of a metal, and the metal may include one or more of niobium (Nb), vanadium (V), or tantalum (Ta).

### CROSS-REFERENCE TO RELATED APPLICATION

This application is based on and claims priority under 35 U.S.C. § 119 to Korean Patent Application No. 10-2024-0016217, filed on Feb. 1, 2024, in the Korean Intellectual Property Office, the disclosure of which is incorporated by reference herein in its entirety.

### BACKGROUND

Various example embodiments relate to a semiconductor device, and/or to an electronic device and a memory device both including the semiconductor device.

Transistors are semiconductor devices that serve as electrical switching devices and are used in various integrated circuit devices including memory devices, integrated circuits (ICs), logic devices, and the like. In order to increase the degree of integration of integrated circuit devices, the space occupied by the transistor is rapidly shrinking, and research is being conducted to reduce the size of the transistor and maintain its performance.

According to the integration of the semiconductor devices, it may be important to improve a subthreshold swing (SS) and an on/off ratio in order to reduce off-current and to clearly distinguish an on/off state, while requiring or having a channel length of tens of nanometers or several nanometers. In addition, it is necessary or desirable to secure thermal and/or electrical safety to improve the reliability of semiconductor devices.

### SUMMARY

Provided is a semiconductor device in which an insertion layer is provided between a channel layer and a gate insulating layer.

Alternatively or additionally provided is an electronic device including a semiconductor device in which an insertion layer is provided between a channel layer and a gate insulating layer.

Alternatively or additionally provided is a memory device in which an insertion layer is provided between a channel layer and a gate insulating layer.

Additional aspects will be set forth in part in the description which follows and, in part, will be apparent from the description, or may be learned by practice of the presented embodiments of the disclosure.

According to various example embodiments, a semiconductor device includes a lower electrode, an upper electrode spaced apart from the lower electrode, a channel layer between the lower electrode and the upper electrode, a gate insulating layer on the channel layer, an insertion layer between the channel layer and the gate insulating layer, and a gate electrode on the gate insulating layer. The channel layer may have a vertical channel structure extending in a vertical direction from the lower electrode toward the upper electrode, and the insertion layer may include a nitride of a metal or an oxynitride of a metal or both a nitride and an oxynitride of a metal, wherein the metal may include one or more of niobium (Nb), vanadium (V), or tantalum (Ta).

Alternatively or additionally according to various example embodiments, a memory device includes a substrate, a channel layer extending in a direction perpendicular to the substrate, a gate insulating layer on the channel layer and including a ferroelectric material, an insertion layer between the channel layer and the gate insulating layer, and a plurality of gate electrodes on the gate insulating layer and stacked in the direction perpendicular to the substrate. The insertion layer may include a nitride of a metal or an oxynitride of a metal or both a nitride of a metal and an oxynitride of a metal, and the metal may include one or more of niobium (Nb), vanadium (V), or tantalum (Ta).

### BRIEF DESCRIPTION OF THE DRAWINGS

The above and other aspects, features, and advantages of certain example embodiments will be more apparent from the following description taken in conjunction with the accompanying drawings, in which:

FIG. 1 schematically illustrates a semiconductor device according to some example embodiments;

FIG. 2 is a graph illustrating a change in a maximum threshold voltage of a semiconductor device;

FIG. 3 schematically illustrates a semiconductor device according to some example embodiments;

FIG. 4 schematically illustrates a semiconductor device according to some example embodiments;

FIG. 5 schematically illustrates a semiconductor device according to some example embodiments;

FIG. 6 is a perspective view schematically illustrating a semiconductor device according to some example embodiments;

FIG. 7 is a cross-sectional view of the semiconductor device taken along line I-I of FIG. 6;

FIG. 8 is a perspective view schematically illustrating a memory device according to some example embodiments;

FIG. 9 is a cross-sectional view of a cell array shown in FIG. 8;

FIG. 10 is an enlarged view of a region B of FIG. 9;

FIG. 11 is a schematic block diagram of a display device including a display driving integrated circuit (DDI) including a semiconductor device according to some example embodiments;

FIG. 12 is a circuit diagram of a complementary metal oxide semiconductor (CMOS) inverter including a semiconductor device according to some example embodiments;

FIG. 13 is a circuit diagram of a CMOS static random access memory (SRAM) device including a semiconductor device according to some example embodiments;

FIG. 14 is a circuit diagram of a CMOS NAND circuit according to some example embodiments;

FIG. 15 is a conceptual diagram schematically showing a device architecture applicable to an electronic device according to some example embodiments;

FIG. 16 is a block diagram of a memory system according to some example embodiments; and

FIG. 17 is a block diagram illustrating a neuromorphic device and an external device connected thereto according to some example embodiments.

### DETAILED DESCRIPTION

Reference will now be made in detail to various embodiments, examples of which are illustrated in the accompanying drawings, wherein like reference numerals refer to like elements throughout. In this regard, example embodiments may have different forms and should not be construed as being limited to the descriptions set forth herein. Accordingly, example embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and/or a method of manufacturing the same according to various embodiments will be described in detail with reference to the accompanying drawings. In the following drawings, the same reference numerals refer to the same components, and the size of each component in the drawings may be exaggerated for clarity and convenience of description. The terms first, second, etc. may be used to describe various components, but the components should not be limited by terms. The terms are used only for the purpose of distinguishing one component from other components.

Singular expressions include plural expressions unless they are explicitly meant differently in context. In addition, when a part “includes” a component, this means that it may include more other components, rather than excluding other components, unless otherwise stated. In addition, the size or thickness of each component in the drawings may be exaggerated for clarity of explanation. Additionally, when a predetermined material layer is described as being on a substrate or another layer, the material layer may exist in direct contact with the substrate or the other layer, or another third layer may exist in between. In addition, since the materials constituting each layer in the embodiments below are only examples, other materials may be used.

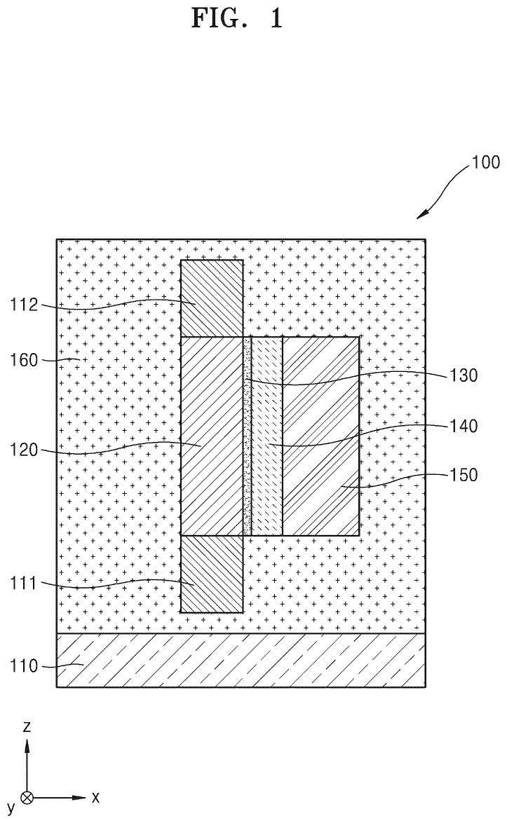

FIG. 1 illustrates a semiconductor device 100 according to some example embodiments.

FIG. 1 may be a cross-sectional illustration of a semiconductor device 100. Referring to FIG. 1, the semiconductor device 100 includes a substrate 110, a lower electrode 111 provided on the substrate 110, a channel layer 120 provided on the lower electrode 111, and an upper electrode 112 provided on the channel layer 120. An insertion layer 130 may be provided on one side of the channel layer 120, a gate insulating layer 140 may be provided on the insertion layer 130, and a gate electrode 150 may be provided on the gate insulating layer 140.

The lower electrode 111, the channel layer 120, and the upper electrode 112 may be sequentially arranged without intervention of other layers in a direction perpendicular to the substrate 110 or an upper surface thereof (e.g., in a z-direction). The channel layer 120 may have a vertical channel structure configured to extend in a vertical direction (z-direction) from the lower electrode 111 toward the upper electrode 112. The lower electrode 111, the channel layer 120, and the upper electrode 112 may have the same width; however, example embodiments are not limited thereto.

The gate electrode 150 may be provided such that a longitudinal direction (z-direction) thereof is the direction perpendicular to the substrate 110. As described herein, the longitudinal direction indicates a direction in which the length direction of the corresponding component is relatively long when viewed in the drawing.

The channel layer 120, the insertion layer 130, the gate insulating layer 140, and the gate electrode 150 may be sequentially arranged in a horizontal direction (x direction) with respect to the substrate 110.

A mold insulating material 160 may be provided on the substrate 110 to fill an empty space. The lower electrode 111 may be spaced apart from the substrate 110 by the mold insulating material 160.

The substrate 110 may be or may include (or be included in) an insulating substrate, or may be a semiconductor substrate having an insulating material formed on a surface thereof. Alternatively or additionally, the substrate 110 may be, include, or be included in, a semiconductor substrate. The semiconductor substrate may include, for example, one or more of Si, Ge, SiGe, or a group III-V semiconductor material. The substrate 110 may be, for example, a silicon substrate having a silicon oxide formed on a surface thereof, but example embodiments are n not limited thereto.

The lower electrode 111 and the upper electrode 112 may include a metal material, and may include the same or different materials. The lower electrode 111 and the upper electrode 112 may independently include at least one selected from among or from the group consisting of tungsten (W), cobalt (Co), nickel (Ni), iron (Fe), titanium (Ti), molybdenum (Mo), chromium (Cr), zirconium (Zr), hafnium (Hf), niobium (Nb), tantalum (Ta), silver (Ag), gold (Au), aluminum (AI), copper (Cu), tin (Sb), vanadium (V), ruthenium (Ru), platinum (Pt), zinc (Zn), and magnesium (Mg), or may include a nitride thereof. A layer including at least one of indium nitride, indium oxide, and indium tin oxide may be further provided on the lower electrode 111 or the upper electrode 112.

The channel layer 120 may be provided between the lower electrode 111 and the upper electrode 112 and may be elongated in a direction (z direction) perpendicular to the substrate 110. For example, the semiconductor device 100 may have a vertical channel structure in which the channel layer 120 is elongated from the lower electrode 111 toward the upper electrode 112. The thickness of the channel layer 120 may be about 3 nm to about 10 nm. The channel layer 120 may include an amorphous oxide semiconductor. The channel layer 120 may include at least one of InGaZnO, In₂O₃, InZnO, and InGaO. In some example embodiments, the channel layer 120 may include a plurality of layers. The channel layer 120 may include In, and the channel layer 120 may be configured such that the content of In increases toward the lower electrode 111. Alternatively or additionally, the channel layer 120 includes In, and the channel layer 120 may be configured so that the content of In increases toward the upper electrode 112. For example, the channel layer 120 may be configured such that the content of In increases toward the lower electrode 111 and/or the upper electrode 112. Alternatively or additionally the channel layer 120 may include a metal oxide. For example, the channel layer 120 may include tungsten (W) oxide. The channel layer 120 may be configured such that the content of the metal oxide increases toward the lower electrode 111 and/or the upper electrode 112. For example, the channel layer 120 may be configured such that the content of tungsten oxide increases toward the lower electrode 111 and/or the upper electrode 112.

The gate electrode 150 may be spaced apart from the channel layer 120. The gate electrode 150 may be arranged to face part or all of the channel layer 120. The gate electrode 150 may include an electrically conductive material. For example, the gate electrode 150 may include a metal or a metal compound and/or polysilicon such as doped polysilicon.

The gate insulating layer 140 may be provided between the channel layer 120 and the gate electrode 150 to electrically disconnect the channel layer 120 from the gate electrode 150. The gate insulating layer 140 may include an insulating material. For example, the gate insulating layer 140 may include a dielectric material.

The insertion layer 130 may be provided between the channel layer 120 and the gate insulating layer 140. The insertion layer 130 may be elongated in the direction (z direction) perpendicular to the substrate 110. The insertion layer 130 may include a nitride of a metal and/or an oxynitride of a metal. Here, the metal may include one or more of niobium (Nb), vanadium (V), or tantalum (Ta). For example, the insertion layer 130 may include at least one of niobium nitride and niobium oxynitride. As a specific example, the insertion layer 130 may include at least one of NbN and NbₓO_{y}N_{z} (1≤x≤5, y>0, 1≤z≤5). A thickness of the insertion layer 130 may be in a range of about 0.5 nm to about 3 nm. In some examples, the thickness of the insertion layer 130 may be in a range of about 1 nm to about 3 nm. Alternatively or additionally, a ratio of a thickness of the insertion layer 130 to a thickness of the channel layer 120 may be in a range of about 0.05 to about 0.3. Meanwhile, the insertion layer may include at least one of vanadium nitride and vanadium oxynitride, or may include at least one of tantalum nitride and tantalum oxynitride.

As described above, in the semiconductor device 100 according to various example embodiments, the insertion layer 130 including at least one of niobium nitride and niobium oxynitride is provided between the channel layer 120 and the gate insulating layer 140, thereby improving the thermal and/or electrical stability of the semiconductor device 100. Alternatively or additionally, the insertion layer 130 including at least one of niobium nitride and niobium oxynitride provided between the channel layer 120 and the gate insulating layer 140 may control the movement of hydrogen and oxygen at the interface between the gate insulating layer 140 and the channel layer 120, thereby increasing reliability.

In some examples, the semiconductor device 100 according to some example embodiments may be used for memory devices and/or logic devices as well as large-area display driving devices because the semiconductor device 100 may have low off-current, low SS, and/or high on/off ratios by applying oxide semiconductors to channel layers. For example, by applying the semiconductor device 100 to a DRAM cell vertical transistor to improve thermal stability, it may be possible to reduce the size of DRAM and increase the memory capacity, and thereby improve integration efficiency.

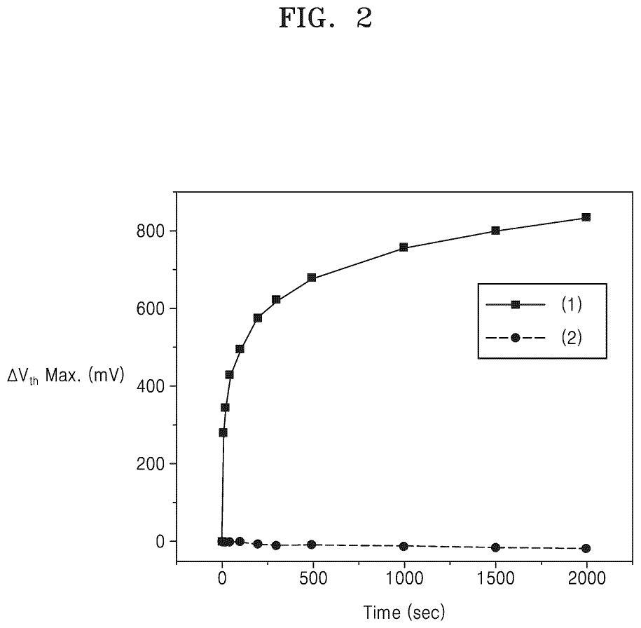

FIG. 2 illustrates a comparison of Positive Bias Thermal Instability (PBTI) measurement results according to an 85° C. stress reaction in a semiconductor device according to a comparative example and the semiconductor device according to example embodiments as described with reference to FIG. 1. Here, the semiconductor device according to the comparative example indicates a semiconductor device in which an insertion layer is excluded from the semiconductor device shown in FIG. 1, and a NbN insertion layer is used as the insertion layer 130 in the semiconductor device according to some example embodiments.

In FIG. 2, line (1) shows a PBTI measurement result of a semiconductor device according to a comparative example, and line (2) shows a PBTI measurement result of the semiconductor device 100 according to some example embodiments shown in FIG. 1. In lines (1) and (2), the thickness of the channel layer 120 is set to about 10 nm, the thickness of the gate insulating layer 140 is set to about 7 nm, and in line (2), the thickness of the insertion layer 130 is set to about 2 nm.

Referring to FIG. 2, in the case of line (1), it may be seen that the value of the maximum threshold voltage change (ΔVₜₕ max) significantly increases as time passes in the 85° C. stress reaction. In particular, it may be seen that the maximum threshold voltage change value increases significantly from approximately 0 mV to 700 mV in a time second from 0 and 500 sec and increases from approximately 700 mV to 800 mV in a time section from 500 sec to 1500 sec. Meanwhile, in the case of line (2), there is no significant change in the maximum threshold voltage change in the entire time section of 0 to 2000 sec in the 85° C. stress response. In particular, compared to a semiconductor device in which a NbN insertion layer is not provided between the channel layer 120 and the gate insulating layer 140, it may be seen that thermal and electrical stability is improved in the semiconductor device 100 provided with the NbN insertion layer 130.

Since the NbN insertion layer 130 is provided between the channel layer 120 and the gate insulating layer 140, a change in threshold voltage in a thermal stress environment may be reduced, and accordingly PBTI may be improved. Alternatively or additionally, device stability may be realized even in a stressful environment by adjusting the interface characteristics of the channel layer 120 and the gate insulating layer 140, and the thermal and electrical stability of the semiconductor device 100 may be improved.

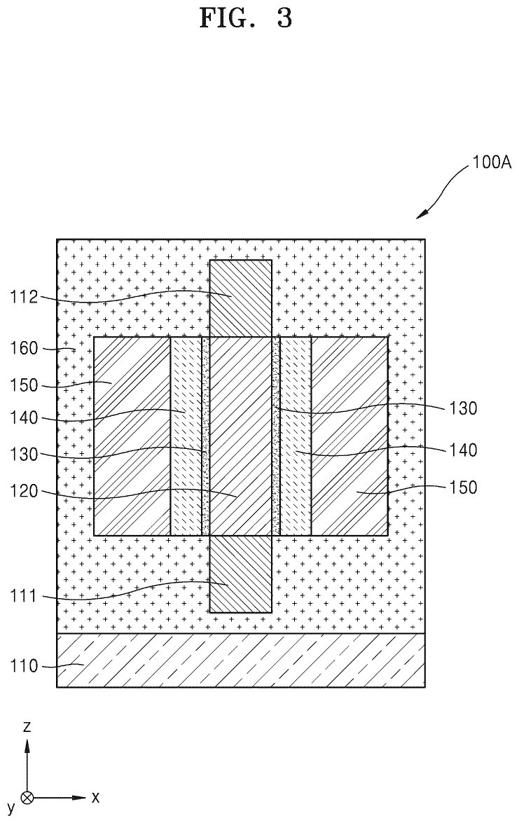

FIG. 3 illustrates a semiconductor device 100A according to various example embodiments. In FIG. 3, components using the same reference numerals as those of FIG. 1 have substantially the same configuration and effect as those described with reference to FIG. 1, and thus a detailed description thereof is omitted.

Referring to FIG. 3, the semiconductor device 100A includes a lower electrode 111, a channel layer 120, and an upper electrode 112 arranged in the direction (z direction) perpendicular to a substrate 110. An insertion layer 130 may be provided around the channel layer 120, a gate insulating layer 140 may be provided around the insertion layer 130, and a gate electrode 150 may be provided around the gate insulating layer 140.

The insertion layer 130 may include a nitride of a metal and/or an oxynitride of a metal. Here, the metal may include one or more of niobium (Nb), vanadium (V), or tantalum (Ta). For example, the insertion layer 130 may include at least one of niobium nitride and niobium oxynitride. The insertion layer 130 may include at least one of NbN and NbₓO_{y}N_{z} (1≤x≤5, y>0, and 1≤z≤5). Meanwhile, the insertion layer may include at least one of vanadium nitride and vanadium oxynitride, and/or may include at least one of tantalum nitride and tantalum oxynitride.

The gate electrode 150 may be provided around the channel layer 120 and the insertion layer 130 to increase an area in which the gate electrode 150 and the channel layer 120 face each other, which may improve a short channel effect. The semiconductor device 100A may be applied to a gate all around (GAA) structure.

Since the semiconductor device 100A according to some example embodiments includes the insertion layer 130 provided between the channel layer 120 and the gate insulating layer 140, the interface characteristics of the channel layer 120 and the gate insulating layer 140 are adjusted, so that device stability may be realized or improved upon even in a stressful environment.

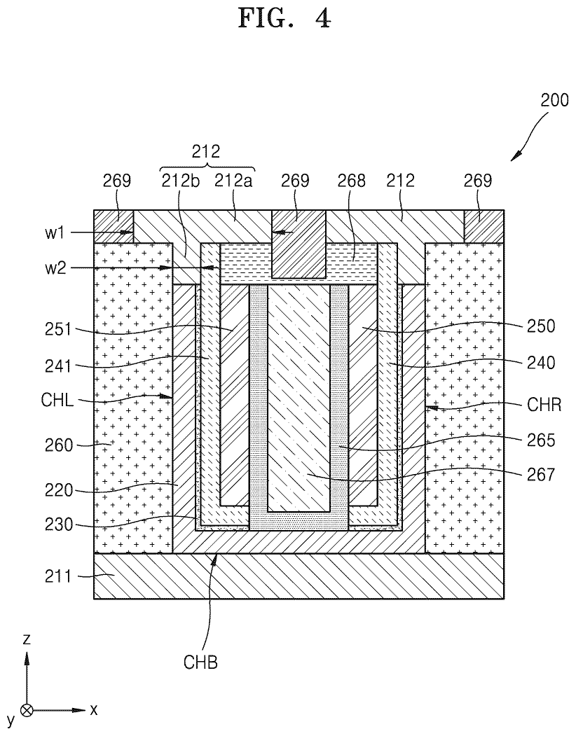

FIG. 4 illustrates a semiconductor device 200 according to some example embodiments.

Referring to FIG. 4, the semiconductor device 200 may include a lower electrode 211, a channel layer 220 provided on the lower electrode 211, and an upper electrode 212 provided on the channel layer 220. The lower electrode 211 may be or correspond to a source electrode, and the upper electrode 212 may be or correspond to a drain electrode, or the lower electrode 211 may be or correspond to a drain electrode, and the upper electrode 212 may be or correspond to a source electrode.

The channel layer 220 may have a U-shaped (or a sharp-U shaped) cross-sectional shape. The channel layer 220 may include a bottom portion CHB in contact with the lower electrode 211, a first vertical extension portion CHR extending in a direction (z direction) perpendicular to the lower electrode 211 from one end of the bottom portion CHB, and a second vertical extension portion CHL extending in the direction (z direction) perpendicular to the lower electrode 211 from the other end of the bottom portion CHB.

A first gate electrode 250 may be provided to be spaced apart from the first vertical extension portion CHR, and a second gate electrode 251 may be provided to be spaced apart from the second vertical extension portion CHL. A first gate insulating layer 240 may be provided between the first vertical extension portion CHR and the first gate electrode 250, and a second gate insulating layer 241 may be provided between the second vertical extension portion CHL and the second gate electrode 251. An insertion layer 230 may be provided on the bottom portion CHB of the channel layer 220, between the first vertical extension portion CHR and the first gate insulating layer 240, and between the second vertical extension portion CHL and the second gate insulating layer 241. Thicknesses of the first gate insulating layer 240 may be the same as, or different from, thicknesses of the second gate insulating layer 241.

The channel layer 220 may include an amorphous oxide semiconductor. The channel layer 220 may include at least one of InGaZnO, In₂O₃, InZnO, and InGaO. In some example embodiments, the channel layer 220 may include a plurality of layers. The channel layer 220 may include In, and the channel layer 220 may be configured such that the content of In increases toward the lower electrode 211 or the upper electrode 212. In some cases, the channel layer 220 may include a metal oxide. For example, the channel layer 220 may include tungsten (W) oxide. The channel layer 120 may be configured such that the content of the metal oxide increases toward the lower electrode 211 and/or the upper electrode 212. For example, the channel layer 220 may be configured such that the content of tungsten oxide increases toward the lower electrode 211 or the upper electrode 212.

The insertion layer 230 may include a nitride of a metal and/or an oxynitride of a metal. For example, the insertion layer 230 may include one or more of niobium (Nb), vanadium (V), or tantalum (Ta). For example, the insertion layer 130 may include at least one of niobium nitride and niobium oxynitride. As a specific example, the insertion layer 230 may include at least one of NbN and NbₓO_{y}N_{z} (1≤x≤5, y>0, 1≤z≤5). Meanwhile, the insertion layer may include at least one of vanadium nitride and vanadium oxynitride, or may include at least one of tantalum nitride and tantalum oxynitride. A thickness of the insertion layer 230 may be in a range of about 0.5 nm to about 3 nm. For example, the thickness of the insertion layer 230 may be in a range of about 1 nm to about 3 nm. Alternatively or additionally, a ratio of a thickness of the insertion layer 230 to a thickness of the channel layer 220 may be in a range of about 0.05 to about 0.3.

The first gate electrode 250 and/or the second gate electrode 251 may extend in a second horizontal direction (y direction). Physical and/or electrical properties of the first gate electrode 250 and the second gate electrode 251, such as thicknesses and/or resistivities, may be the same as, or different from, each other. The first gate electrode 250 and the second gate electrode 251 may be spaced apart from each other. The first gate electrode 250 and/or the second gate electrode 5251 may constitute a word line (a row line). The electrical signal input to the first gate electrode 250 may not match the electrical signal input to the second gate electrode 251. The first gate electrode 250 may control the channel of the first vertical extension portion CHR, and the second gate electrode 251 may control the channel of the second vertical extension portion CHL.

An insulating liner 265 may be arranged between the first gate electrode 250 and the second gate electrode 251, which are spaced apart from each other. The insulating liner 265 may be conformally arranged on the sidewalls of the first gate electrode 250 and the second gate electrode 251 facing each other and/or the upper surfaces of the channel layer 220. The insulating liner 265 may have a top surface arranged on the same plane as the first gate electrode 250 and the second gate electrode 251. The insulating liner 265 may include, for example, silicon nitride. A buried insulating material 267 may fill a space between the first gate electrode 250 and the second gate electrode 251 spaced apart from each other on the insulating liner 265. The buried insulating material 267 may include, for example, silicon oxide. An upper insulating material 268 may be arranged on upper surfaces of the first gate electrode 250, the second gate electrode 251, and/or the buried insulating material 267. The top surface of the upper insulating material 268 may be arranged at the same level as the top surface of a mold insulating material 260.

An upper electrode 212 may be arranged on the channel layer 220. The upper electrode 212 may serve as a landing pad. The upper electrode 212 may include an upper left electrode and an upper right electrode. The upper right electrode may be electrically connected to the first vertical extension portion CHR. The upper left electrode may be electrically connected to the second vertical extension portion CHL. The upper right electrode and the upper left electrode may not be electrically connected to each other. The upper electrode 212 may include an upper portion 212a and a lower portion 212b having different widths. The upper portion 212a of the upper electrode 212 may be arranged at a higher level than (or above) the top surface of the mold insulating material 260. The lower portion 212b of the upper electrode 212 may be arranged inside a recess defined between the mold insulating material 260 and the upper insulating material 268. In some example embodiments, the upper portion 212a of the upper electrode 212 may have a first width w1 in the first horizontal direction (x direction), and the lower portion 212b of the upper electrode 212 may have a second width w2 less than the first width w1 in the first horizontal direction (x direction). The lower portion 212b of the upper electrode 212 may be arranged inside the recess, and the upper portion 212a of the upper electrode 212 may have a bottom surface arranged on the top surface of the mold insulating material 260 and the top surface of the upper insulating material 268 on the lower portion 212b of the upper electrode 212, and accordingly, the upper electrode 212 may have a T-shaped vertical cross section. The bottom surface of the lower portion 212b of the upper electrode 212 may be in contact with the upper surfaces of the first vertical extension portion CHR and/or the second vertical extension portion CHL. First and second (both) sidewalls of the lower portion 212b of the upper electrode 212 may be aligned with both sidewalls of the first vertical extension portion CHR and the second vertical extension portion CHL. The bottom surface of the lower portion 212b of the upper electrode 212 may be arranged at a higher level than the top surface of the first gate electrode 250 and/or the top surface of the second gate electrode 251, and a portion of the sidewall of the lower portion 212b of the upper electrode 212 may be covered by the first gate insulating layer 240 and/or the second gate insulating layer 241. An insulating material 269 surrounding the upper electrode 212 may be arranged on upper surfaces of the mold insulating material 260 and the upper insulating material 268. The semiconductor device 200 may have a vertical channel transistor (VCT) structure including the channel layer 220 extending in a vertical direction (z direction) to the lower electrode 211. The second gate insulating layer 241 may have an L-shaped cross section (or a sharp-L shaped cross section), and the first gate insulating layer 240 may have a cross-sectional shape symmetrical to the second gate insulating layer 241 based on the buried insulating material 267. The first gate electrode 250 and the second gate electrode 251 may have a straight cross-sectional shape. Alternatively, the first gate insulating layer 240 and the second gate insulating layer 241 may have a straight cross-sectional shape like the first gate electrode 250 and the second gate electrode 251.

As described above, since the semiconductor device 200 according to some example embodiments includes the insertion layer 230 provided between the channel layer 220 and the gate insulating layer 240, the interface characteristics of the channel layer 220 and the gate insulating layer 240 are adjusted, so that device stability may be realized even in a stressful environment.

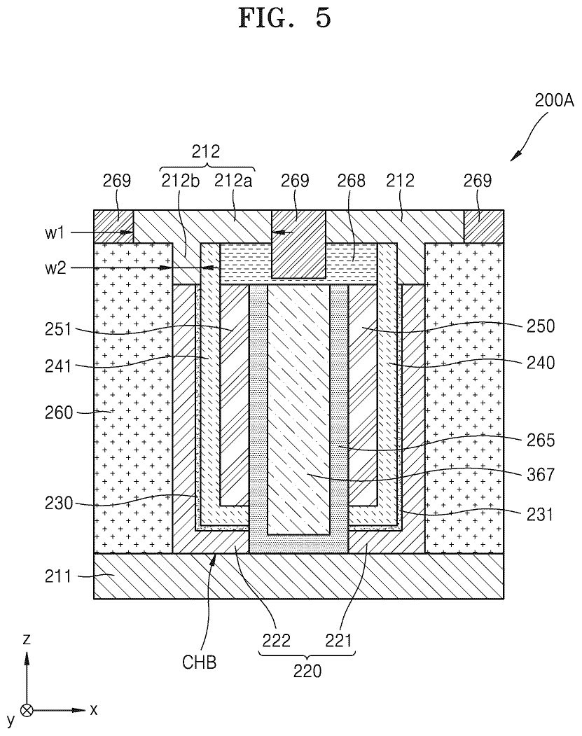

FIG. 5 illustrates a semiconductor device 200A according to some example embodiments. In FIG. 5, components using the same reference numerals as those of FIG. 4 have substantially the same configuration and effect as those described with reference to FIG. 4, and thus a detailed description thereof is omitted.

When FIG. 5 is compared to FIG. 4, the shape of the channel layer 220 may be different from that of FIG. 4. The channel layer 220 may include a first channel layer 221 and a second channel layer 222, having the same or different thicknesses. The first channel layer 221 and the second channel layer 222 may be provided symmetrically with respect to the buried insulating material 267. Each of the first channel layer 221 and the second channel layer 222 has an L-shaped cross section, and the first channel layer 221 and the second channel layer 222 may be provided to face each other. The first channel layer 221 and the second channel layer 222 may have shapes symmetrical to z-direction. Each of the first channel layer 221 and the second channel layer 222 may have a long-side which is arranged in a direction (z direction) perpendicular to the substrate (not shown).

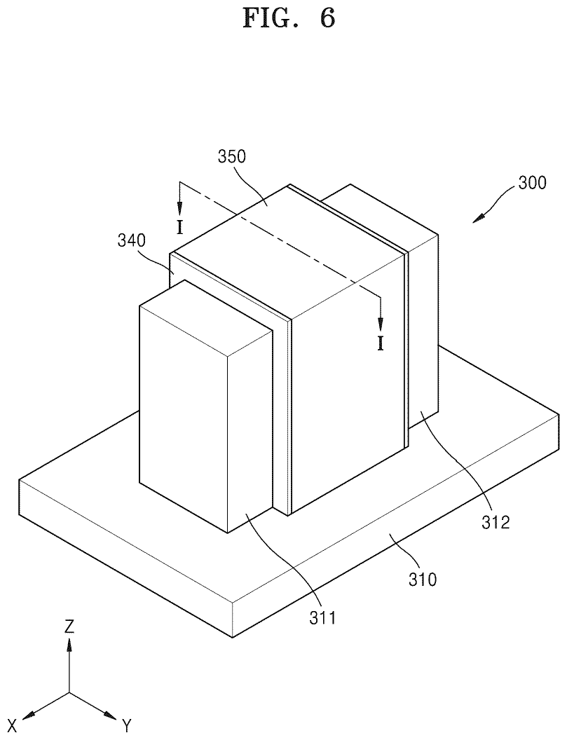

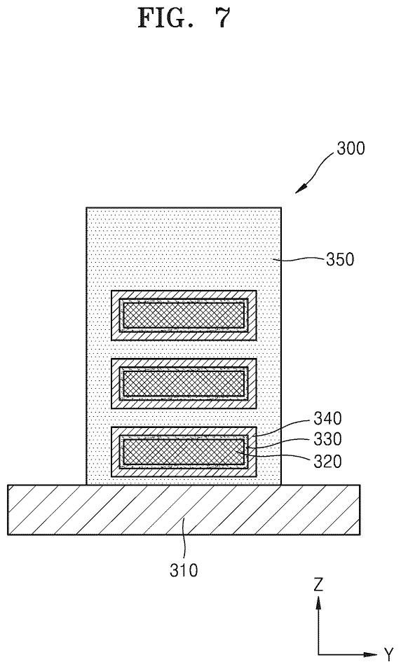

FIG. 6 is a perspective view illustrating a schematic structure of a semiconductor device 300 according to some example embodiments, and FIG. 7 is a cross-sectional view of the semiconductor device 300 taken along line I-I of FIG. 6. The I-I cross section may represent a cross-section taken (in the Y-direction in the drawing) across a space between a source electrode 311 and a drain electrode 312 in a direction perpendicular to a substrate 310 (in the Z-direction in the drawing). Here, since the substrate 310 may not be a complete plane, the vertical direction may include not only a substantial vertical direction but also a general vertical direction.

Referring to FIGS. 6 and 7, the semiconductor device 300 according to various example embodiments may include the substrate 310, the source electrode 311 arranged on the substrate 310, the drain electrode 312 arranged to be spaced apart from the source electrode 311, a channel layer 320 connected between the source electrode 311 and the drain electrode 312, an insertion layer 330, a gate insulation layer 340, and a gate electrode 350 provided to be insulated from the source electrode 311 and the drain electrode 312. The semiconductor device 300 may be a field effect transistor.

The substrate 310 may be or may include (or be included in) an insulating substrate, or may be a semiconductor substrate having an insulating material formed on a surface thereof. The semiconductor substrate may include, for example, one or more of Si, Ge, SiGe, or a group III-V semiconductor material. The substrate 310 may be, for example, a silicon substrate having a silicon oxide formed on a surface thereof, but is not limited thereto.

The channel layer 320 may extend in one direction parallel to the substrate 310. For example, the channel layer 320 may be provided in a nano wire shape extending in one direction or may be provided in a nano sheet shape extending in one plane. A plurality of channel layers 320 according to some example embodiments may be provided. The number of channel layers 320 may be three, or two, or more than three; example embodiments are not limited thereto. A thickness of each of the channel layers 320 may be the same, or different from, one another. A vertical spacing between adjacent channel layers 320 may be constant, or may be variable. The plurality of channel layers 320 may be arranged to be spaced apart from each other in a direction perpendicular to the substrate 310 (Z direction). In particular, the neighboring channel layers 320 may be separated from each other and arranged in the first direction (Z direction). The channel layer 320 may be in contact with (or direct contact with) the source electrode 311 and/or the drain electrode 312. However, example embodiments are not limited thereto, and it is also possible for the channel layer 320 to be connected to the source electrode 311 and/or the drain electrode 312 through another medium.

The channel layer 320 may include an amorphous oxide semiconductor. The channel layer 320 may include at least one of InGaZnO, In₂O₃, InZnO, and InGaO. The channel layer 320 may include a plurality of layers. The channel layer 320 may include In, and the channel layer 320 may be configured such that the content of In increases toward the source electrode 311 or the drain electrode 312. The channel layer 320 may include a metal oxide. For example, the channel layer 320 may include tungsten (W) oxide. The channel layer 320 may be configured such that the content of the metal oxide increases toward the source electrode 311 or the drain electrode 312. For example, the channel layer 320 may be configured such that the content of tungsten oxide increases toward the source electrode 311 or the drain electrode 312.

The insertion layer 330 may be provided to surround the channel layer 320. The insertion layer 330 may include a nitride of a metal or an oxynitride of a metal. For example, the insertion layer 330 may include niobium (Nb), vanadium (V), or tantalum (Ta). For example, the insertion layer 330 may include at least one of niobium nitride and niobium oxynitride. As a specific example, the insertion layer 330 may include at least one of NbN and NbₓO_{y}N_{z} (1≤x≤5, y>0, 1≤z≤5). A thickness of the insertion layer 330 may be in a range of about 0.5 nm to about 3 nm. In particular, the thickness of the insertion layer 330 may be in a range of about 1 nm to about 3 nm. Alternatively or additionally, a ratio of a thickness of the insertion layer 330 to a thickness of the channel layer 320 may be in a range of about 0.05 to about 0.3. A thickness of each insertion layer 330 may be the same, or may be different from one another.

The gate insulating layer 340 may be provided to surround the insertion layer 330. A thickness of different gate insulating layers 340 may be the same, or may be different from one another. The gate electrode 350 to be described later, the source electrode 311, and the drain electrode 312 may be insulated from each other by the gate insulating layer 340. The gate insulating layer 340 may be a dielectric layer having a high dielectric constant (high-k). The gate insulating layer 340 may include, one or more of, for example, a metal-oxide containing Hf or Zr, a metal-oxide-nitride containing Hf or Zr, or materials in which Ti, Ta, Al, or one of lanthanides-based materials is doped into the metal-oxide or the metal-oxide-nitride.

The gate electrode 350 is arranged on the gate insulating layer 340 and may be provided to surround the channel layer 320, the insertion layer 330, and the gate insulating layer 340. As an example, the gate electrode 350 may be arranged to surround the entire sides of the channel layer 320 and the insertion layer 330. Accordingly, the semiconductor device 300 according to some example embodiments may be provided as a field effect transistor GAA FET having a gate all around structure. For example, the gate electrode 350 may include at least one of metal, metal-carbide, metal-nitride, metal-silicide, metal-silicon-nitride, silicon, and graphene-based materials. The semiconductor device 300 according to some example embodiments may be provided in a three-dimensional structure such as a field effect transistor having a gate all around structure.

Since the semiconductor device 300 according to some example embodiments includes the insertion layer 330 provided between the channel layer 320 and the gate insulating layer 340, the interface characteristics of the channel layer 320 and the gate insulating layer 340 are adjusted, so that device stability may be realized even in a stressful environment.

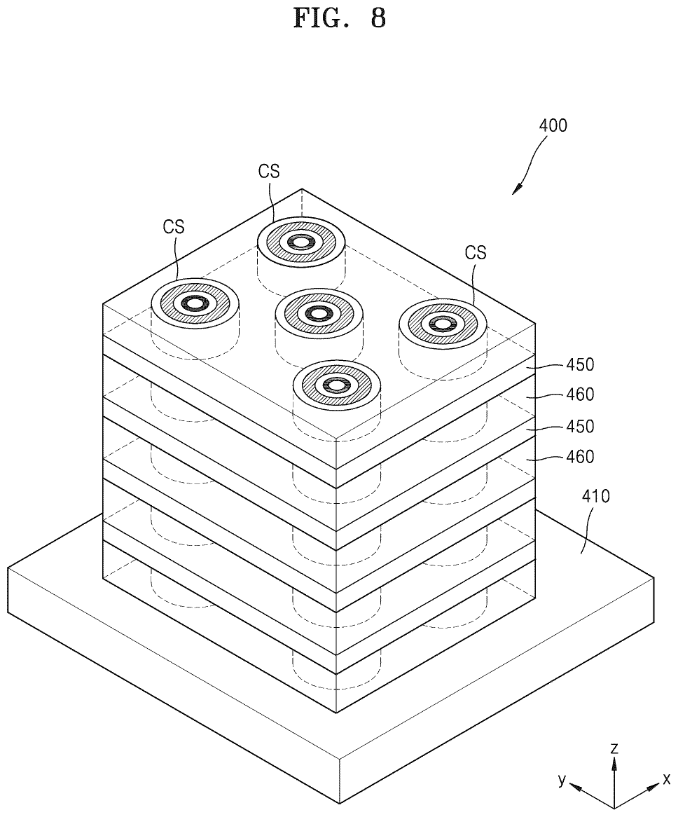

FIG. 8 is a perspective view schematically illustrating a memory device 400 according to some example embodiments. The memory device 400 illustrated in FIG. 8 may be or may correspond to a vertical NAND flash memory device; however, example embodiments are not limited thereto, and the memory device 400 illustrated in FIG. 8 may be or may correspond to another type of non-volatile memory.

Referring to FIG. 8, the memory device 400 includes a plurality of cell arrays CS arranged on a substrate 410. Here, each cell array CS may be provided to extend in a direction perpendicular to the substrate 410 (z-axis direction in FIG. 8). The plurality of cell arrays CS may be arranged on the substrate 410 in various forms.

An interlayer insulating material 460 and a gate electrode 450 are alternately stacked on the substrate 410 in the direction perpendicular to the substrate 410. Each interlayer insulating material 460 and each gate electrode 450 may be provided in parallel to the substrate 410. The substrate 410 may include various materials. For example, the substrate 410 may include, but is not limited to, a single crystal silicon substrate, a compound semiconductor substrate, or a silicon on insulator (SOI) substrate. Alternatively or additionally, for example, an impurity area by doping or implantation, an electronic device such as a transistor, or a peripheral circuit that selects and controls memory cells (MC) that store data, may be further included on the substrate 410.

The gate electrode 450 may include, for example, a metal material having good (excellent) electrical conductivity such as one or more of gold (Au), a metal nitride, silicon doped with impurities, or a two-dimensional conductive material. However, in addition to this being merely an example, the gate electrode 450 may include various other materials. A word line may be electrically connected to the gate electrode 450.

The interlayer insulating material 460 may serve as a spacer layer for insulation between the gate electrodes 450. The interlayer insulating material 460 may include, for example, silicon oxide, silicon nitride, or the like, but is not limited thereto. A channel hole is formed in the interlayer insulating materials 460 and the gate electrodes 450 to penetrate in the direction perpendicular to the substrate 410 (z-axis direction). Such a channel hole may be formed to have, for example, a circular cross section. A gate insulating layer 440, an insertion layer 430, and a channel layer 420 are sequentially provided on the inner wall of the channel hole as described later.

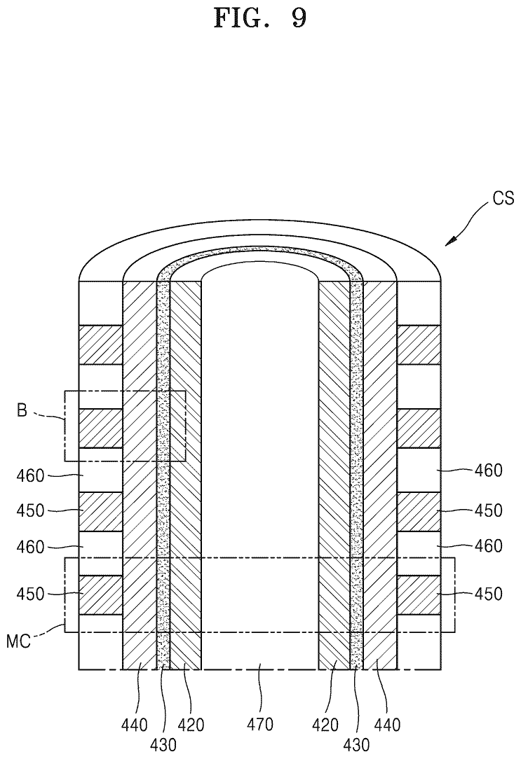

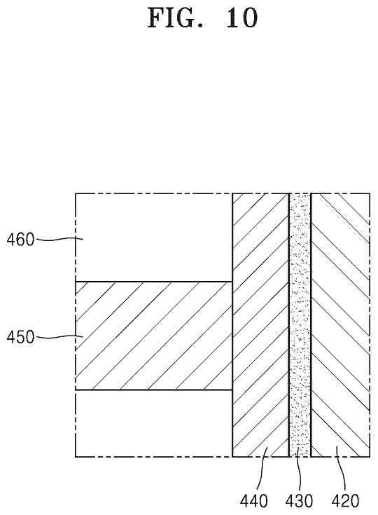

FIG. 9 is a cross-sectional view of a cell array CS shown in FIG. 8, and FIG. 10 is an enlarged view of a region B of FIG. 9.

Referring to FIGS. 9 and 10, each cell array CS includes a plurality of memory cells MC stacked in a direction perpendicular to a substrate 410 (z-axis direction). The cell array CS includes a plurality of gate electrodes 450 stacked to be spaced apart from each other in z-axis direction, and a gate insulating layer 440, an insertion layer 430, and a channel layer 420, which are sequentially provided inside the gate electrodes 450 in a direction perpendicular to the z-axis direction. Each of the gate insulating layer 440, the insertion layer 430, and the channel layer 420 is provided to extend perpendicularly to the substrate 410 and may be shared by the plurality of memory cells MCs. The gate insulating layer 140 may include a ferroelectric insulating material. An intermediate layer may be further provided between the channel layer 420 and the gate insulating layer 440. The intermediate layer may include an insulating material (e.g., Al₂O₃ or SiO₂). A filling insulating layer 470 may be provided inside the channel layer 420 to fill the channel hole. The filling insulating material 470 may include, for example, silicon oxide or air, but is not limited thereto.

A number of gate electrodes 450 and a number of interlayer insulating materials 460 is not limited to what is illustrated in FIG. 9. Additionally or alternatively, a thickness of each of the interlayer insulating materials 460 may be the same as, or different from, that of the neighboring gate electrodes 450.

Each memory cell MC may include the particular (e.g., predetermined) gate electrode 450, and the gate insulating layer 440, the insertion layer 430, and a channel layer 420 corresponding to each gate electrode 450. A source and a drain may be provided below and above the channel layer 420, respectively, and a channel corresponding to the gate electrode 450 may be formed in the channel layer 420 between the source and the drain.

The channel layer 420 may include a semiconductor material. For example, the channel layer 420 may include one or more of Si, Ge, SiGe, Group III-V semiconductor, etc. Alternatively or additionally, the channel layer 420 may include, for example, an amorphous oxide semiconductor, a nitride semiconductor, an oxynitride semiconductor, a two-dimensional (2D) semiconductor material, a quantum dot (QD), or an organic semiconductor. Here, the 2D semiconductor material may include, for example, transition metal dichalcogenide (TMD) or graphene, and quantum dots may include colloidal QDs, nanocrystal structures, etc. However, this is only an example, and embodiments are not limited thereto. The channel layer 420 may include at least one of InGaZnO, In₂O₃, InZnO, and InGaO. The channel layer 420 may include a plurality of layers.

The insertion layer 430 may include a nitride of a metal or an oxynitride of a metal. For example, the insertion layer 430 may include niobium (Nb), vanadium (V), or tantalum (Ta). For example, the insertion layer 430 may include at least one of niobium nitride and niobium oxynitride. As a specific example, the insertion layer 430 may include at least one of NbN and NbₓO_{y}N_{z} (1≤x≤5, y>0, 1≤z≤5). A thickness of the insertion layer 430 may be in a range of about 0.5 nm to about 3 nm. Alternatively, the thickness of the insertion layer 430 may be in a range of about 1 nm to about 3 nm. A ratio of a thickness of the insertion layer 430 to a thickness of the channel layer 420 may be in a range of about 0.05 to about 0.3.

As described above, since the memory device 400 according to some example embodiments includes the insertion layer 430 provided between the channel layer 420 and the gate insulating layer 440, the interface characteristics of the channel layer 420 and the gate insulating layer 440 are adjusted, so that device stability may be realized even in a stressful environment.

The semiconductor devices 100, 100A, 200, and 300, and the memory device 400 according to the embodiments may be applied to, for example, one or more of transistors, field effect transistors (FETs), semiconductor memory devices, logic devices, image sensors, and the like. The logic devices are responsible for operation and control, and the memory devices are responsible for storing information. The logic devices may be applied to microcomponents, analog ICs, logic ICs, or the like. The analog ICs may include power semiconductors, image sensors, touch controllers, and the like. The logical ICs may include display driver ICs (DDIs), timing controllers (T-CONs), media ICs, application processors (APs), vehicle semiconductors, and the like. The memory devices may include DRAMs, SRAMs, NAND memories, and the like.

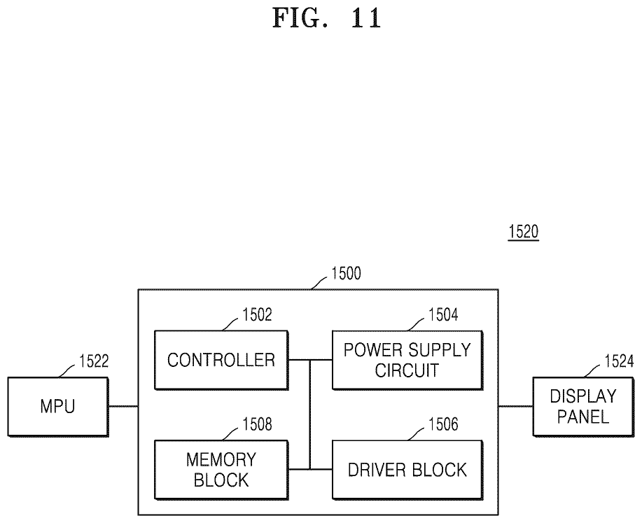

FIG. 11 is a schematic block diagram of a display device 1520 including a display driver IC (DDI) 1500 according to some example embodiments.

Referring to FIG. 11, the DDI 1500 may include a controller 1502, a power supply circuit unit 1504, a driver block 1506, and a memory block 1508. The controller 1502 receives and decodes a command applied from a main processing unit (MPU) 1522, and controls each block of the DDI 1500 to implement an operation according to the command. The power supply circuit unit 1504 generates a driving voltage in response to the control of the controller 1502. The driver block 1506 drives a display panel 1524 by using the driving voltage generated by the power supply circuit unit 1504 in response to the control of the controller 1502. The display panel 1524 may be a liquid crystal display panel or a micro LED device. The memory block 1508 is a block for temporarily storing a command input to the controller 1502 or control signals output from the controller 502, or storing necessary data, and may include a memory such as a RAM, a ROM, or the like. The power supply circuit unit 1504 and the driver block 1506 may include the semiconductor device according to the embodiment described above.

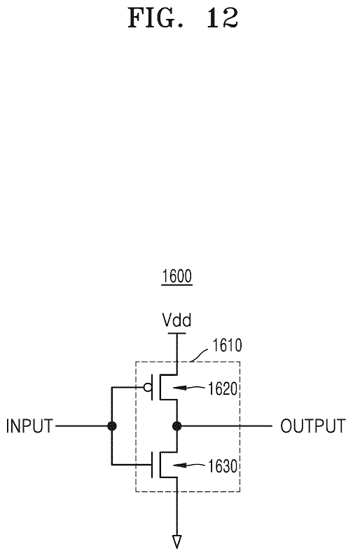

FIG. 12 is a circuit diagram of a CMOS inverter according to some example embodiments.

Referring to FIG. 12, the CMOS inverter 1600 includes a CMOS transistor 1610. The CMOS transistor 1610 includes a PMOS transistor 1620 and an NMOS transistor 1630 connected between a power terminal Vdd and the ground terminal. The CMOS transistor 1610 may include the semiconductor device according to the embodiment described above, for example as either or both of the PMOS transistor 1620 and the NMOS transistor 1630.

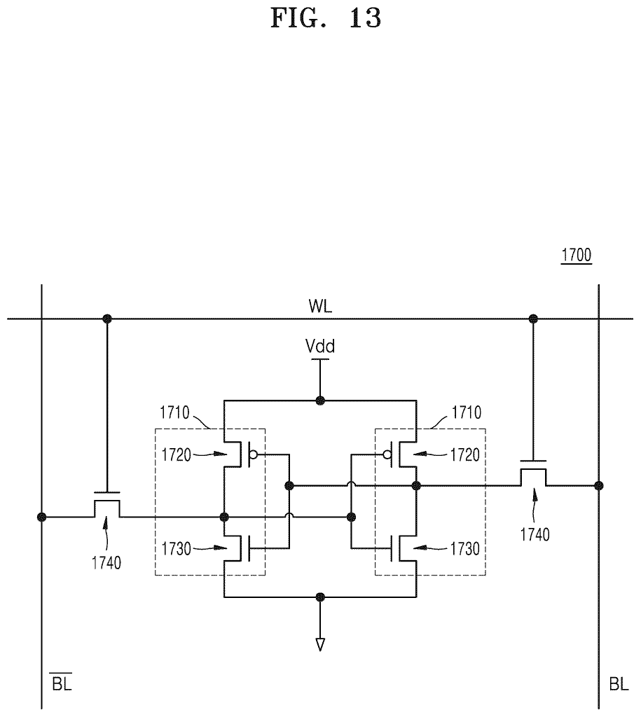

FIG. 13 is a circuit diagram of a CMOS SRAM device 1700 according to some example embodiments.

Referring to FIG. 13, the CMOS SRAM device 1700 includes a pair of driving transistors 1710. Each of the pair of CMOS transistors 1710 includes a PMOS transistor 1720 and an NMOS transistor 1730 connected between the power terminal Vdd and the ground terminal. The CMOS SRAM device 1700 may further include a pair of transfer transistors 1740. A source of the transfer transistor 1740 is cross-connected to a common node of the PMOS transistor 1720 and the NMOS transistor 1730 constituting the driving transistor 1710. The power terminal Vdd is connected to a source of the PMOS transistor 1720, and the ground terminal is connected to a source of the NMOS transistor 1730. A word line WL may be connected to the gates of the pair of transfer transistors 1740, and a bit line BL and an inverted bit line may be connected to the drains of the pair of transfer transistors 740, respectively.

At least one of the driving transistor 1710 and the transmission transistor 1740 of the CMOS SRAM device 1700 may include the semiconductor device according to various example embodiment described above. For example, one or more of the transistors 1740, 1720, 1730, may include at least one of the various example embodiments described above.

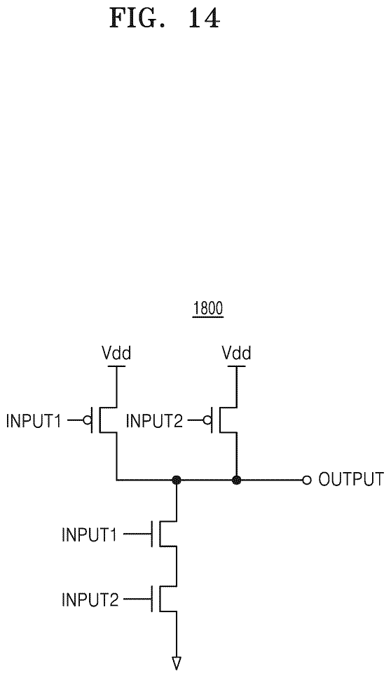

FIG. 14 is a circuit diagram of a CMOS NAND circuit 1800 according to some example embodiments.

Referring to FIG. 14, the CMOS NAND circuit 1800 includes a pair of CMOS transistors to which different input signals are transferred. The CMOS NAND circuit 1800, for example one or more of the transistors, may include the semiconductor device according to various example embodiments described above.

The semiconductor device and the memory device according to the embodiments may be used in various electronic devices.

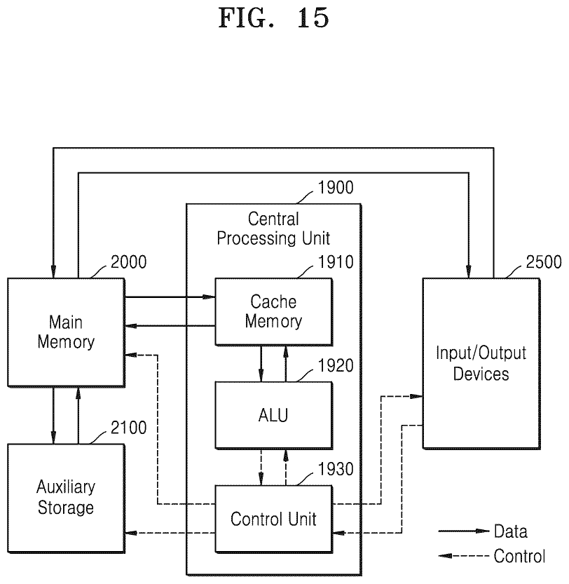

FIG. 15 is a conceptual block diagram schematically illustrating a device architecture applicable to an electronic device according to embodiments.

Referring to FIG. 15, a cache memory 1910, an arithmetic logic unit (ALU) 1920, and a control unit 1930 may form a central processing unit (CPU) 1900, and the cache memory 1910 may include a static random access memory (SRAM). A main memory (or a memory system) 2000 and an auxiliary storage 2100 may be provided separately from the CPU 1900. The main memory 2000 may include a DRAM device, and the auxiliary storage 2100 may include the semiconductor device or memory device described above. In some cases, the device architecture may be implemented in a form in which computing unit elements and memory unit elements are adjacent to each other in one chip without division of sub-units.

The semiconductor device or the memory device according to the embodiment described above may be implemented as a memory block in the form of a chip and used as a neuromorphic computing platform, or may be used to construct a neural network.

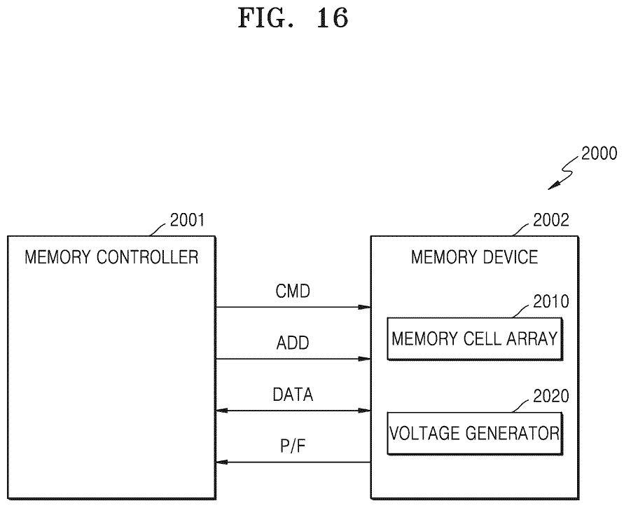

FIG. 16 is a block diagram of a memory system 2000 according to some example embodiments.

Referring to FIG. 16, the memory system 2000 may include a memory controller 2001 and a memory device 2002. The memory controller 2001 performs a control operation on the memory device 2002, and for example, the memory controller 2001 provides an address ADD to the memory device 2002 and a command CMD for programming (or writing), reading, and/or erasing operations on the memory device 2002. In some cases, data for programming operations and reading data may be transmitted between the memory controller 2001 and the memory device 2002.

The memory device 2002 may include a memory cell array 2010 and a voltage generator 2020. The memory cell array 2010 may include a plurality of memory cells, and may include a memory device according to the embodiment described above.

The memory controller 2001 may include one or more of a processing circuit such as hardware including a logic circuit, a hardware/software combination such as processor execution software, or a combination thereof. For example, processing circuits include, but are not limited to, central processing units (CPUs), arithmetic logic units (ALUs), digital signal processors, microcomputers, field programmable gate arrays (FPGA), system-on-chips (SoCs), programmable logic units, microprocessors, and application-specific integrated circuits (ASICs). The memory controller 2001 may operate in response to a request from a host (not shown) and may be configured to convert the memory controller 2001 into a special purpose controller by accessing the memory device 2002 and controlling the control operation (e.g., write/read operation) discussed above. The memory controller 2001 may generate an address ADD and a command CMD for performing a programming/read/erase operation on the memory cell array 2010. In addition, in response to a command from the memory controller 2001, the voltage generator 2020 (e.g., a power circuit) may generate a voltage controlled signal for controlling the voltage level of the word line for data programming or data reading in the memory cell array 2010.

Alternatively or additionally, the memory controller 2001 may perform a determination operation on data read from the memory device 2002. For example, the number of on-cells and/or off-cells may be determined from data read from the memory cell. The memory device 2002 may provide a pass/fail signal P/F to the memory controller 2001 according to a read result of the read data. The memory controller 2001 may control write and read operations of the memory cell array 2010 with reference to the pass/fail signal P/F.

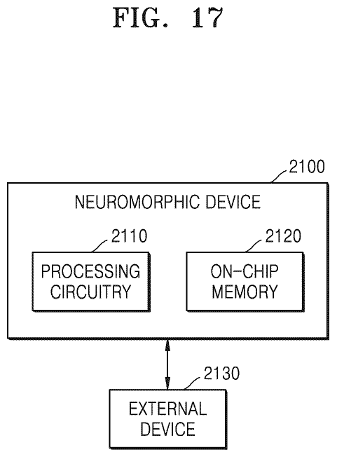

FIG. 17 is a block diagram illustrating a neuromorphic device 2100 and an external device connected thereto according to some example embodiments.

Referring to FIG. 17, the neuromorphic device 2100 may include a processing circuitry 2110 and/or a memory 2120. The neuromorphic device 2100 may include a semiconductor device or a memory device according to the embodiment described above.

In some example embodiments, the processing circuitry 2110 may be configured to control functions for driving the neuromorphic device 2100. For example, the processing circuitry 2110 may be configured to control the neuromorphic device 2100 by executing a program stored in the memory device 2120. In some embodiments, the processing circuitry may include hardware such as a logic circuit, a hardware/software combination such as a processor executing software, or a combination thereof. For example, the processor may include, but is not limited to, a CPU, a GPU, an AP included in the neuromorphic device 2100, an ALU, a digital signal processor, a microcomputer, a FPGA, a SoC, a programmable logic unit, a microprocessor, an ASIC, etc. In some embodiments, the processing circuitry 2110 may be configured to read/write various data with respect to the external device 2130, and/or execute the neuromorphic device 2100 using the read/recorded data. In some embodiments, the external device 2130 may include an external memory and/or sensor array having an image sensor (e.g., a CMOS image sensor circuit).

In some example embodiments, the neuromorphic device of FIG. 17 may be applied to a machine learning system. Machine learning systems may utilize a variety of artificial neural network organization and processing models, such as a convolutional neural network (CNN), a deconvolutional neural network, a repeated neural network (RNN) selectively including a long short-term memory (LSTM) unit, and/or a gated recurrent unit (GRU), a stacked neural network (SNN), a state-space dynamic neural network (SSDNN), a Deep Faith Network (DBN), a Generative Adversarial Network (GAN), and/or a limited Boltzmann machine (RBM).

Alternatively or additionally, these machine learning systems may include other types of machine learning models, such as linear and/or logistic regression, statistical clustering, Bayesian classification, decision tree, dimension reduction such as principal component analysis, expert systems, and/or combinations thereof, including ensembles such as random forests. Such machine learning models may be used to provide various services and/or applications, for example, image classification services, user authentication services based on biometric information or biometric data, advanced driver assistance system (ADAS) services, voice assistant services, and automatic speech recognition (ASR) services may be executed by electronic devices.

According to various example embodiments, the semiconductor device and the memory device with improved thermal and electrical stability may be implemented by including the insertion layer including at least one of niobium nitride and niobium oxynitride between the channel layer and the gate insulating layer.

Any or all of the elements described with reference to FIGS. 16 and/or 17 may communicate with any or all other elements described with reference to FIGS. 16 and/or 17. For example, any element may engage in one-way and/or two-way and/or broadcast communication with any or all other elements in FIGS. 16 and/or 17, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

Any or all of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

It should be understood that various embodiments described herein should be considered in a descriptive sense only and not for purposes of limitation. Descriptions of features or aspects within each embodiment should typically be considered as available for other similar features or aspects in other embodiments, and example embodiments are not necessarily mutually exclusive with one another. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a lower electrode;
an upper electrode spaced apart from the lower electrode;
a channel layer between the lower electrode and the upper electrode;
a gate insulating layer on the channel layer;
an insertion layer between the channel layer and the gate insulating layer; and
a gate electrode on the gate insulating layer, wherein
the channel layer has a vertical channel structure extending in a vertical direction from the lower electrode toward the upper electrode, and
the insertion layer includes a nitride of a metal or an oxynitride of a metal, or both a nitride of a metal and an oxynitride of a metal, wherein the metal includes at least one of niobium (Nb), vanadium (V), or tantalum (Ta).

2. The semiconductor device of claim 1, wherein the insertion layer comprises at least one of NbN and NbₓO_{y}N_{z} (1≤x≤5, y>0, and 1≤z≤5).

3. The semiconductor device of claim 1, wherein a thickness of the insertion layer is 0.5 nm to 3 nm.

4. The semiconductor device of claim 1, wherein a ratio of a thickness of the insertion layer to a thickness of the channel layer is 0.05 to 0.3.

5. The semiconductor device of claim 1, wherein the channel layer comprises an amorphous oxide semiconductor.

6. The semiconductor device of claim 1, wherein the channel layer comprises at least one of InGaZnO, In₂O₃, InZnO, and InGaO.

7. The semiconductor device of claim 1, wherein
the channel layer comprises indium, and at least one of
a content of indium in the channel layer increases toward the upper electrode or a content of indium in the channel layer increases toward the lower electrode.

8. The semiconductor device of claim 1, wherein
the channel layer comprises tungsten oxide, and at least one of
a content of tungsten oxide in the channel layer increases toward the upper electrode or a content of tungsten oxide in the channel layer increases the lower electrode.

9. The semiconductor device of claim 1, wherein the gate electrode has a gate-all-around structure surrounding the channel layer.

10. The semiconductor device of claim 1, wherein the channel layer has a U-shaped cross section.

11. The semiconductor device of claim 1, wherein the channel layer includes a first channel layer and a second channel layer, each having an L-type cross-section, and the first channel layer and the second channel layer are arranged to face each other.

12. The semiconductor device of claim 11, wherein the gate electrode includes a first gate electrode corresponding to the first channel layer and a second gate electrode corresponding to the second channel layer.

13. An electronic device including the semiconductor device in claim 1.

14. A memory device comprising:
a substrate;
a channel layer extending in a direction perpendicular to the substrate;
a gate insulating layer on the channel layer and including a ferroelectric material;
an insertion layer between the channel layer and the gate insulating layer; and
a plurality of gate electrodes on the gate insulating layer and stacked in the direction perpendicular to the substrate, wherein
the insertion layer comprises a nitride of a metal or an oxynitride of a metal or both a nitride of a metal and an oxynitride of a metal, and the metal comprises at least one of niobium (Nb), vanadium (V), or tantalum (Ta).

15. The memory device of claim 14, wherein the channel layer comprises at least one of NbN and NbₓO_{y}N_{z} (1≤x≤5, y>0, and 1≤z≤5).

16. The memory device of claim 14, wherein the ferroelectric material comprises at least one of hafnium oxide, zirconium oxide, and hafnium-zirconium oxide.
a

17. The memory device of claim 14, wherein a thickness of the insertion layer is 0.5 nm to 3 nm.

18. The memory device of claim 14, wherein a ratio of a thickness of the insertion layer to a thickness of the channel layer is 0.05 to 0.3.

19. The memory device of claim 14, wherein the channel layer comprises an amorphous oxide semiconductor.

20. The memory device of claim 14, wherein the channel layer comprises at least one of InGaZnO, In₂O₃, InZnO, and InGaO.
